(19) United States
(12) Patent Application Publication
(10) Pub. No.: US 2011/0256674 A1
(43) Pub. Date: Oct. 20, 2011

(54) Two-way Halo Implant

(75) Inventor: Katsura Miyashita, Naka-gun (JP)

(73) Assignee: KABUSHIKI KAISHA TOSHIBA, Tokyo (JP)

(21) Appl. No.: 13/170,370

(22) Filed: Jun. 28, 2011

Related U.S. Application Data
(62) Division of application No. 12/396,855, filed on Mar. 3, 2009.
(60) Provisional application No. 61/034,329, filed on Mar. 6, 2008.

(51) Int. Cl. H01L 21/8232

(52) U.S. Cl. 438/186; 257/E21.615

(57) ABSTRACT

A system and method for ion implantation during semiconductor fabrication. An integrated circuit may be designed with proximately located one-directional transistor gates. A two-way halo ion implantation is performed perpendicularly to the transistor gates in order to embed the dopant into the silicon body on the surface of the semiconductor wafer. The two-way halo both reduces the channeling effect by allowing ion implantation beneath the transistor gate, and reduces the halo shadowing effect resulting from halo implanting which is done parallel to the transistor gates.

### RELATED APPLICATIONS

The present application is a divisional of U.S. application Ser. No. 12/396,855, filed Mar. 3, 2009, entitled “Two-Way Halo Implant,” which is a non-provisional of U.S. Provisional Application Ser. No. 61/034,329, filed Mar. 6, 2008, entitled “Two-Way Halo Implant,” the contents of which are incorporated herein by reference in their entirety for all purposes.

### TECHNICAL FIELD

Aspects of the present invention are generally directed to semiconductor devices and their methods for manufacture, and more particularly to providing a way to dope regions of a transistor while reducing the shadowing effect of angled ion implantation.

### BACKGROUND

Ion implantation, also known as doping, is one of the key technologies in the fabrication of semiconductor integrated circuit devices. With current ion implanters, a very accurate and extremely pure dose of a desired atomic species can be introduced into a target material. For example, boron ions may be directed from an ion source towards a semiconductor substrate with an accelerator, and may penetrate the silicon body of a semiconductor surface at a desired dosage level.

Angled ion implantation, also known as tilted or “halo” implantation, involves embedding ions into a material at the semiconductor surface at an angle that is not normal to the semiconductor surface. Halo implants are commonly used in semiconductor fabrication to control the short channel effect under transistor gates or other masking structures formed on the semiconductor surface, which may disrupt the ion implantation to the semiconductor surface regions beneath the transistor gate or other structure. However, while a halo implantation may control the short channel effect, such an implantation may produce an implant “shadow” near the gate on the side opposite the ion source, where implantation is obstructed within an area shadowed by the gate. The location and size of the shadow area depends on the direction of the implant, the implant angle, and the height and profile of the transistor gate. This shadowing effect limits the ability to distribute ions at the proper locations and at the proper dosage level into the semiconductor surface, and may limit size reduction and design flexibility during semiconductor fabrication.

### SUMMARY

In light of the foregoing background, there is a need to reduce the shadowing effect resulting from angled ion implantations, thereby possibly permitting size reductions and increasing device design flexibility during semiconductor fabrication. In one aspect of the present disclosure, a two-way halo ion implantation may be performed on an integrated circuit. Each ion implantation may direct ions of a particular composition downward onto and/or into a silicon layer surface of the semiconductor device, at an angle not normal to the surface. The implantation may be on opposing sides of a long axis of one or more transistor gates form on the semiconductor surface.

According to another aspect of the present disclosure, the two-way halo implants may be configured perpendicular to the transistor gates to direct ion implantation onto and/or into regions of the silicon layer beneath the gates, thereby potentially controlling the short channel effect under the transistor gates. According to yet another aspect of the present disclosure, the circuit, such as an SRAM, may be designed with proximately located one-directional transistor gates, so that certain halo implanting parallel to those gates may be unnecessary. Thus, shadowing effect of transistor gates may be effectively reduced, thereby potentially lowering the required ion concentration in certain portions of the silicon layer, along with the ion concentration differential between adjacent regions resulting from gate shadowing.

These and other aspects of the disclosure will be apparent upon consideration of the following detailed description of illustrative embodiments.

### BRIEF DESCRIPTION OF THE DRAWINGS

Reference will now be made to the accompanying drawings, which are not necessarily drawn to scale, and wherein:

FIG. 1 is a schematic block diagram showing an integrated circuit design schematic built in accordance with a semiconductor fabrication process;

FIG. 2 is a schematic block diagram showing an overhead view of a transistor built in accordance with a semiconductor fabrication process;

FIG. 3 is a schematic block diagram showing a side view of a transistor built in accordance with a semiconductor fabrication process;

FIG. 4 is a illustrative block diagram showing a side view portion of an integrated circuit compatible with an embodiment of the present disclosure;

FIG. 5 is a schematic block diagram showing an integrated circuit design schematic built in accordance with an embodiment of the present disclosure;

FIG. 6 is a schematic block diagram showing an overhead view of a transistor built in accordance with an embodiment of the present disclosure; and

FIG. 7 is a schematic block diagram showing a side view of a transistor built in accordance with an embodiment of the present disclosure.

### DETAILED DESCRIPTION

Illustrative embodiments will now be described more fully with reference to the accompanying drawings. The embodiments set forth herein should not be viewed as limiting; rather, these embodiments are provided merely as examples of the concepts described herein.

It is noted that various connections are set forth between elements in the following description. It is noted that these connections in general and, unless specified otherwise, may be direct or indirect and that this specification is not intended to be limiting in this respect.

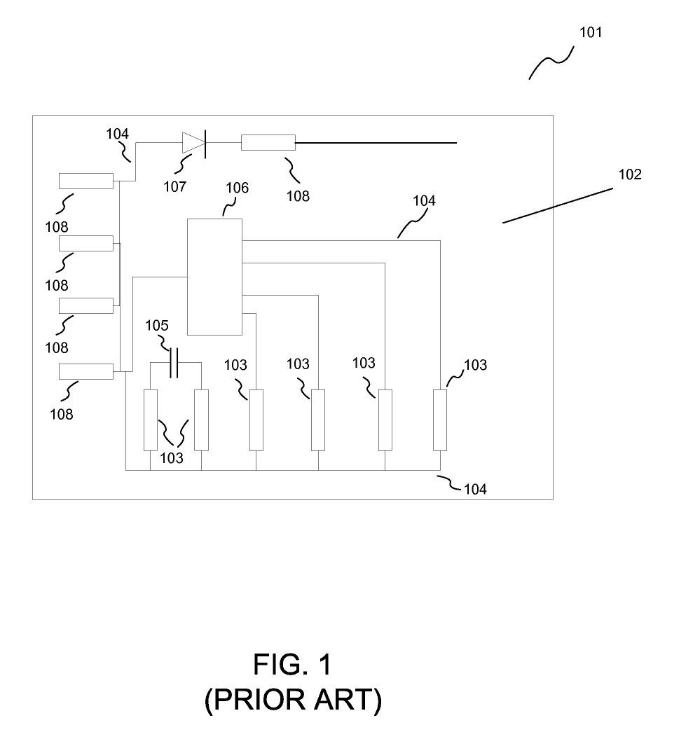

FIG. 1 shows a design of an illustrative integrated circuit 101. Various circuit components 103-108 are formed on a substrate 102 using semiconductor fabrication processes. The position and directional orientation of the transistor gates 103 and 108 are determined by the circuit design, an attempt to best achieve the functional and design goals of the semiconductor device. Thus, the circuit 101 contains certain transistors 103 positioned with a directional orientation that is in an up-down direction of FIG. 1 and certain other transistors 108 positioned with a directional orientation that is in a left-right direction of FIG. 1.

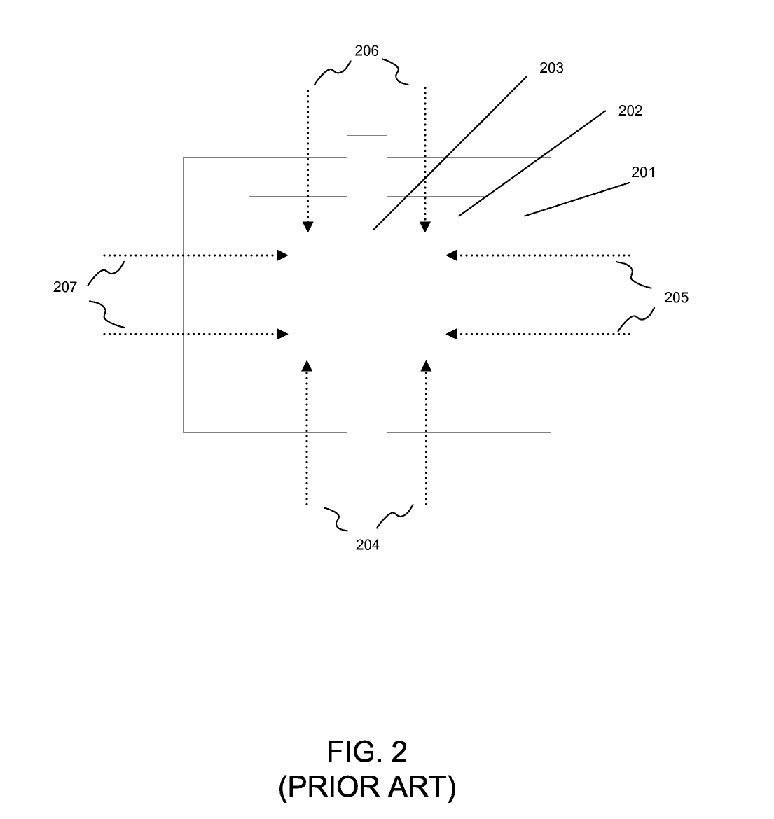

FIG. 2 shows an illustrative block diagram of an overhead view of a single transistor from the circuit 101. The transistor gate 203 is formed on a silicon body 202, which is built on a substrate 201, such as a buried oxide (BOX) layer. Thus, in this embodiment, substrate 201 and silicon body 202 may be configured as part of a silicon on insulator (SOI) structure. Four halo implants 204-207 direct ions into the silicon body 202 from different angles that are not normal to the silicon body 202 surface. This four-way implantation is used so that ions may be embedded beneath the long edges of both the up-down oriented transistor gates and the left-right oriented transistor gates. The halo implants 204 and 206 are parallel to transistor gate 203, while halo implants 205 and 207 are perpendicular to gate 203. Thus, with respect to transistor gate 203, and any other similarly oriented gates in the same integrated circuit, only halo implants 205 and 207 may effectively control the short channel effect. In contrast, halo implants 204 and 206 may add little or no value towards controlling the short channel effect and indeed detriments the performance of the transistor. Similarly, for transistor gates 108 of circuit 101 positioned perpendicularly to gate 203, only halo implants 204 and 206 may effectively reduce the channeling effect, while halo implants 205 and 207 may add little or no value towards controlling the short channel effect and indeed detrimentally affects the performance of those transistors.

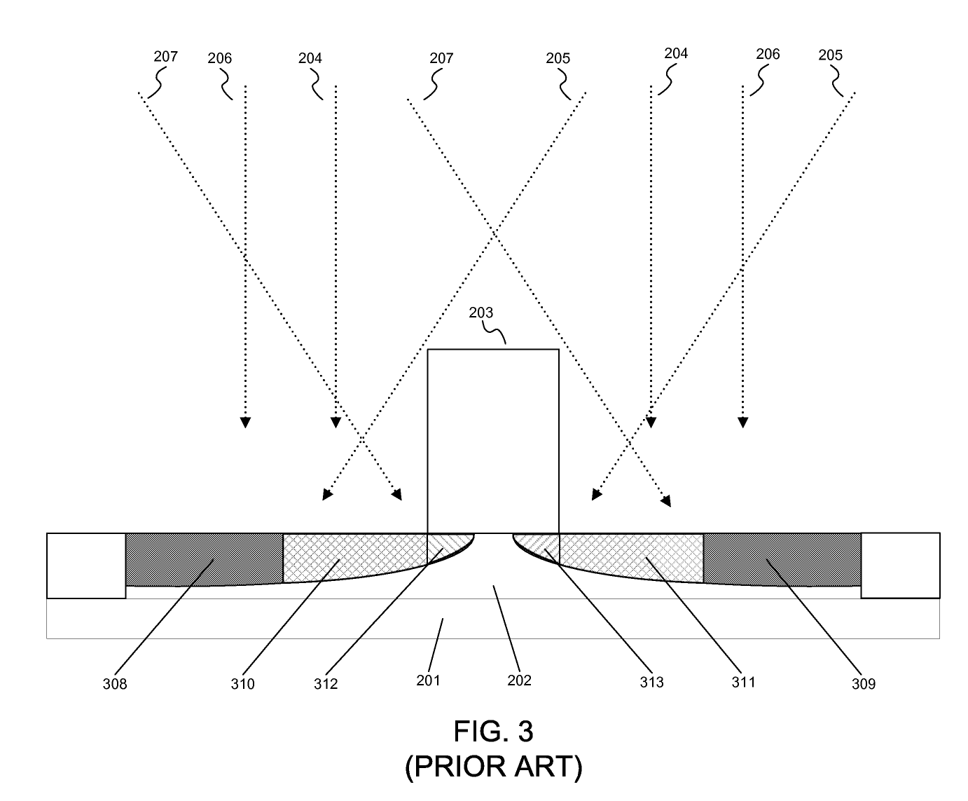

FIG. 3 shows an illustrative block diagram of a cross-section view of the transistor gate 203, along with the underlying silicon body 202 and substrate 201 shown in FIG. 2, facing directly into the long axis of transistor gate 203. The halo implants 204-207 are shown embedding ions into the silicon body 202, into six approximate ion penetration regions 308-313 within the silicon body 202. The ion dosage level of each ion penetration region may depend on the number of halo implants sending ions to the region. For example, regions 312 and 313 may each only receive embedded ions from a single halo implant, halo implants 207 and 205, respectively. In contrast, regions 310 and 311 may each receive ions from three ion implants, but are in the shadow area of the fourth halo implant. In other words, halo implant 207 is blocked by gate 203 from reaching region 311, and halo implant 205 is blocked by gate 203 from reaching region 310. Regions 308 and 309 may receive ions from all four halo implants 204-207.

These ion penetration regions 308-313 illustrate the shadowing effect of transistor gate 203 when using four-way halo implantation. The large number of ion penetration regions 308-313, the large differential in dosage among regions, and the high overall implant dosage in some regions, may cause threshold voltage scattering within a transistor and threshold voltage mismatch between multiple transistors in the same circuit. For example, a static random access memory (SRAM) may use multiple transistors positioned closely together, making the SRAM particularly vulnerable to the shadowing effects of a four-way halo. A high implant dosage may also require the use of a high external resistance, and may cause reverse junction leakage at the gate edge, which may in turn increase the reverse junction current to forward junction current ratio (IR/IF) of the transistor.

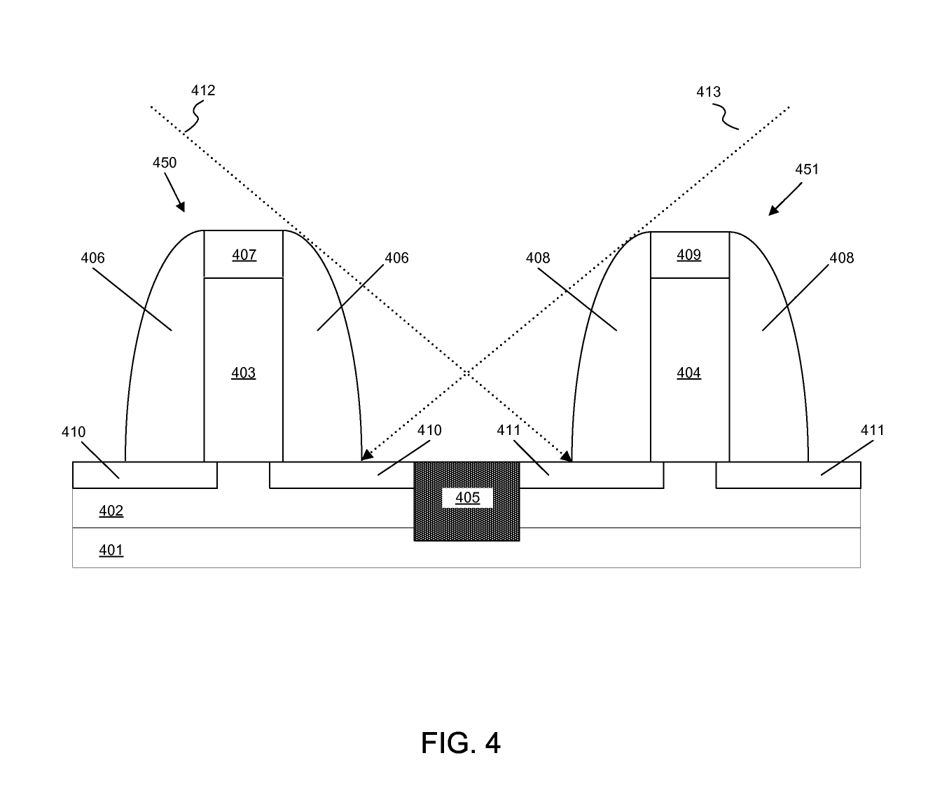

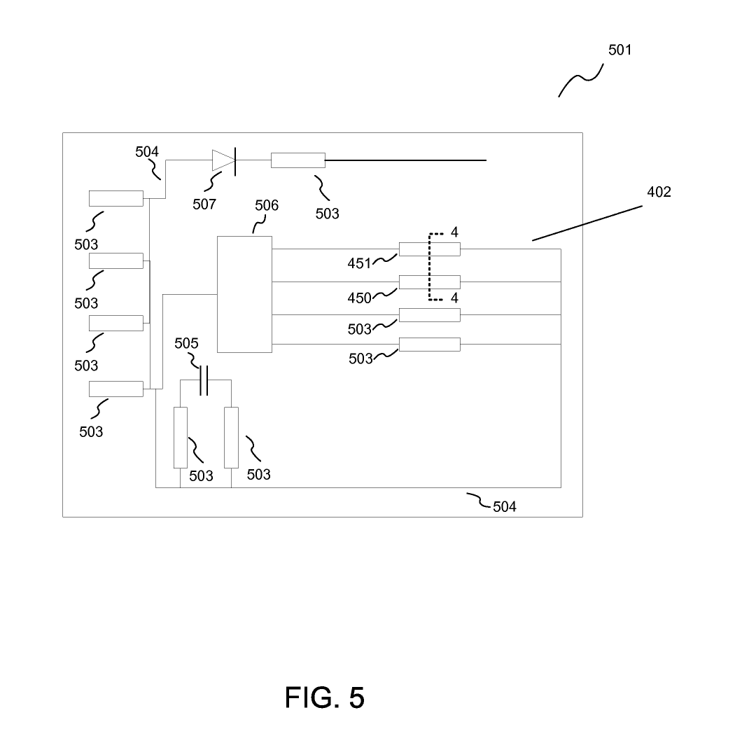

A more detailed description of illustrative devices and manufacturing processes will now be discussed in connection with FIGS. 4-7. Referring to FIG. 4, a view of a portion of a multi-transistor integrated circuit is shown, taken along cross section 4-4 as shown in FIG. 5. This circuit may be, for example, formed on a conventional silicon on insulator (SOI) wafer. However, the circuit may alternatively be formed on a different layer or set of layers, such as on a basic silicon wafer as opposed to an SOI structure. As is shown in FIG. 4, a silicon body 402 may be formed on top of a buried oxide (BOX) layer 401. The silicon body 402 may have an embedded shallow trench isolation (STI) layer 405, which may be used to separate the active areas of two adjacent transistors in a semiconductor device. Silicon body 402 may be, for example, approximately 50-70 nm thick, and the STI layer 405 may be, for example, approximately 60-80 nm thick. Thus, where the silicon body 402 is disposed on the BOX layer 401, the STI layer 405 may extend slightly into the BOX layer 401. The BOX layer 401 may be disposed on a semiconductor substrate (not shown), and may be, for example, approximately 150 nm thick.

Two adjacent conductive transistor gates 403 are 404 (e.g., polysilicon) are formed on the silicon body 402. Transistor gates 403 and 404 may be part of, for example, an n-type field-effect transistor (NFET) 450 adjacent to a p-type field-effect transistor (PFET) 451, both of which are formed in a conventional manner in and on the silicon body 402 on opposing sides of STI layer 405. Transistor gates 403 and 404 may be disposed on silicon body 402 with a thin gate oxide layer (not shown) between the gates 403, 404 and the silicon body 402. In addition, transistor gates 403 and 404 may be re-oxidized in a conventional manner, resulting in an approximately 5 nm wide re-oxidation layer, not shown, on the sidewalls of gates 403 and 404.

Caps 407 and 409 may be formed on top of transistor gates 403 and 404, respectively. Caps 407 and 409 may be formed, for example, by depositing a layer of SiN on top of gates 403 and 404, so that each cap 407 and 409 has a thickness of approximately 50 nm thick or less. Sidewall spacers 406 and 408 may be formed on both sides of gates 403 and 404 and on silicon body 402, and may be formed differently depending on the gate type. For example, mask layer 406 may be a second SiN layer deposited over NFET gate 403, while conventional reactive-ion etching (RIE) may be performed using patterned photo resist layer as a mask to result in spacers 408 on the sidewalls of the PFET gate 404. Sidewall spacers 406 and 408 may each be, for example, approximately 40 nm in width. Doped source/drain regions 410 and 411 may be embedded in the silicon body 402.

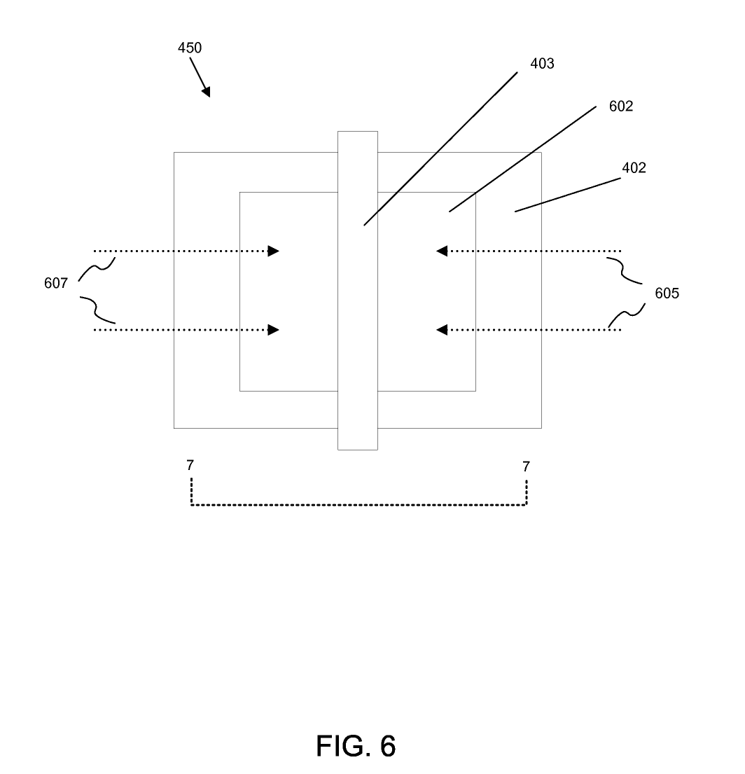

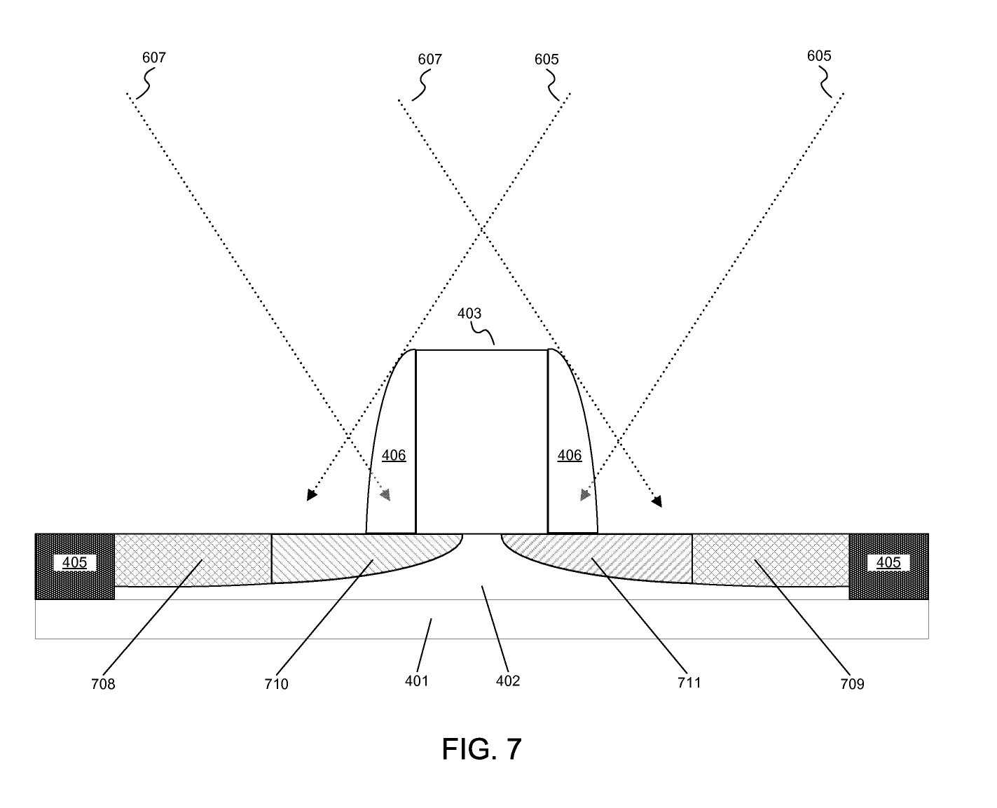

Referring to FIG. 5, the design schematic of an illustrative integrated circuit 501 is shown. Circuit 501 includes the silicon body 402, upon which various circuit components 450, 451, and 503-507 may be formed. The transistors 450, 451, and 503, connectors 504, and other circuit components 505-507, may be formed in and/or on the silicon body 402 and/or at other levels as determined by the functional and design considerations of the integrated circuit 501. Circuit designers may have flexibility with regard to the position and directional orientation of the various circuit components. Indeed, in this example, circuit 501 has been designed so that every transistor 450, 451, and 503 has a gate that is oriented in the same left-right direction. That is, each up-down facing transistor from the illustrative schematic of FIG. 1 has been changed to a left-right facing transistor in this illustrative schematic, while the circuit functionality and connectivity has been preserved. Thus, in this example, all of the transistor gates in the entire circuit 501 are oriented in the same direction. However, all circuit components, or even all transistor gates, need not face the same direction to realize the potential advantages set forth in the present disclosure. For instance, forming sets of one directional proximately located transistor gates may have additional advantages related to reducing the shadowing effect of halo implantation. These potential advantages may result from a two-way halo implantation, such as those shown in FIGS. 6-7, and such as are described in further detail below.

FIG. 6 shows an illustrative block diagram of an overhead view of a transistor 450. Unlike the conventional four-way halo implantation shown in FIG. 2, a two-way halo implantation is used in this example. Halo implants 605 and 607 may direct ions, for example, boron ions, into the silicon body 602, at a non-normal angle relative to the semiconductor surface, from opposite sides of the transistor gate 403. The implant angle of halo implants 605 and 607 may be based on the height of one or more adjacent circuit components (e.g., transistor 451) and the distance between transistor gate 403 and these adjacent components. For instance, referring again to FIG. 4, the angle of halo implant 412 may be determined based on the height of the transistor gate 403 (taking into account the height and width of cap 407 and sidewall spacer 406), the location and width of transistor gate 404 (taking into account sidewall spacer 408), and the distance between the transistor gates 403 and 404, so that the implant may have a more sharp angle (and potentially the sharpest possible angle) for embedding ions into the drain region 411 beneath gate 404. Similarly, the angle of halo implant 413 and the other angled implants on the circuit may be configured based on the height of the various circuit components and distances between nearby components.

Referring again to FIG. 6, since halo implants 605 and 607 are positioned so that the path traveled by the ions is perpendicular to the transistor gate 403 (i.e., perpendicular to the long axis of the gate 403), this two-way halo may evenly embed ions beneath the long edges of the transistor gate 403. Because in this example all of the transistors are facing the same direction, only a two-way halo implant is needed, and so the short channel effect for transistor 450 may be more effectively controlled.

FIG. 7 is a view of cross-section 7-7 in FIG. 6, facing directly into the long axis of transistor gate 403. FIG. 7 also illustrates a potential reduced shadowing effect of using only two halo implants instead of four. A cross-section view of the BOX layer 401, the silicon body 402, and the halo implants 605 and 607 are also shown. As described above, in relation to the conventional four-way halo implantation shown in FIG. 3, ion penetration regions 708-711 may form in the silicon body 602. The ion penetration regions 708-711 as approximately shown may have ion dosage levels differing from adjacent regions, since the ion concentration of each ion penetration region 708-711 may depend on the number of halo implants sending ions to that region.

To illustrate the reduced shadowing effect in this embodiment, halo implant 605 directs ions into the silicon body 402, and specifically into regions 708, 709, and 711. However, since region 710 is hidden, or blocked, by the transistor gate 403, ions from halo implant 605 may not reach this region in any significant quantity. Similarly, halo implant 607 may deliver ions into silicon body regions 708, 709, and 710, but region 711 may be shadowed from halo implant 607 by the transistor gate 403.

Thus, in this example, the two-way implantation from halo implants 605 and 607 into the silicon body 402 near the transistor gate 403, results in only four distinct ion penetration regions 708-711. Regions 708 and 709 contain ions from both halo implants 605 and 607. Region 710 contains embedded ions from halo implant 607, but is in the shadow area of halo implant 605, and therefore might not contain ions from halo implant 605. Similarly, region 709 is shadowed from halo implant 607, but does contain embedded ions from halo implant 605. Thus, regions 710 and 711 may have a lower ion concentration as a result of the implant dosage than regions 708 and 709, but may have the similar or same ion concentration as each other. For instance, where the dosages of halo implants 605 and 607 are equal to each other, regions 710 and 711 each may have approximately half the ion concentration as each of regions 708 and 709.

As illustrated by FIG. 7, the ion penetration regions 708-711 in the silicon body 402 may have a reduced shadowing effect compared to the ion penetration regions of a conventional four-way halo implantation shown in FIGS. 2-3. Since no halo implants are configured parallel to the long axis of the transistor gate, no additional shadowing effect will result. For example, the increased shadowing effect in FIG. 3, resulting from halo implants 204 and 206, may be avoided, thus reducing the overall halo shadowing effect on the transistor. Unlike the silicon body 202 from FIG. 3, which had six distinct ion penetration regions 308-313 with three distinct implant dosage levels, the silicon body 402 in this example has just four ion penetration regions 708-711 with just two distinct ion concentrations result from implants 605 and 607.

FIG. 7 further illustrates that overall implant dosage ion concentration may be reduced using a two-way halo implant during the semiconductor fabrication process. Thus, threshold voltage scattering may be reduced, and instances of threshold voltage mismatch between multiple transistors in the same circuit may be reduced or even eliminated. For example, multiple transistors used to form an SRAM may be positioned much closer together than conventional logic designs using field-effect transistors. Therefore, SRAMs may be more vulnerable to the shadowing effects of a four-way halo, and more prone to threshold voltage mismatch between transistors in the same SRAM.

Additionally, the reduction in implant dosage may allow for a corresponding reduction in external resistance, without necessarily requiring a change in the threshold voltage of the transistor. Further, when a two-way halo implant is applied to a SOI field-effect transistor, reverse junction leakage may be reduced at the gate edge as a result of the lower well implant dosage. This reduction may improve the IR/IF ratio of the transistor.

A potential benefit from a two-way halo implant relates to the use of chemical resist in semiconductor microlithography. During the lithographic process, a layer of photosensitive chemical resist may be applied to a surface of the semiconductor wafer. The wafer surface may then be exposed to a form of radiant energy, such as ultraviolet light projected through a mask onto the surface of the wafer, resulting in physical or chemical changes to the exposed resist layer. The surface may then be rinsed with an appropriate substance, such as a chemical solvent, to form a conductive layer in a desired image on the semiconductor surface. The two-way implant may take place after the application of the resist but before the undeveloped resist is removed with the solvent rinse.

While the foregoing descriptions and the associated drawings may relate to a semiconductor fabrication process, many modifications and other embodiments will come to mind to one skilled in the art having the benefit of the teachings presented. The illustrative embodiments described herein may be adaptable to any manufacturing process that uses a particle implantation into a material.

1. A method for manufacturing a semiconductor device, comprising:
forming a conductive layer on a top surface of a silicon layer, the conductive layer having a width and a length, wherein the length of the conductive layer extends along an axis and is longer than the respective width;
forming a layer of resist on said conductive layer;
directing a first ion stream toward the silicon layer at a first angle not normal to the top surface of the silicon layer, said first angle being perpendicular to the axis;
directing a second ion stream toward the silicon layer at a second angle not normal to the top surface of the silicon layer, said second angle being perpendicular to the axis, wherein said second ion stream originates from an opposite side of the axis from which the first ion stream originates; and
removing at least some of said layer of resist from said conductive layer, wherein only two ion streams are directed toward the silicon layer between steps of forming said layer of resist and removing at least of the said layer of resist.

2. The method of claim 1, wherein the top surface of the silicon layer is not doped by an ion stream directed at an angle parallel to the axis.

3. The method of claim 1, wherein the first and second ion streams are each boron ion streams.

4. The method of claim 1, wherein the conductive layer comprises a plurality of regions of polysilicon.

5. The method of claim 4, further comprising:
forming an SRAM comprising a plurality of transistor gates, wherein said plurality of regions of polysilicon comprise said transistor gates of said SRAM.

6. The method of claim 5, wherein said first ion stream and said second ion stream are directed toward the silicon layer at an angle based on the height one or more of the plurality of transistor gates and a distance between two or more of the plurality of transistor gates.
